(19) United States
(12) Patent Application Publication
(10) Pub. No.: US 2026/0356081 A1
(43) Pub. Date: Nov. 12, 2026

(54) ELASTIC MEMBER AND DISPLAY DEVICE COMPRISING SAME

(71) Applicant: LG INNOTEK CO., LTD., Seoul (KR)

(72) Inventors: Joon Hyuk YANG, Seoul (KR); Jung Min GWAK, Seoul (KR); Jong Min LEE, Seoul (KR)

(73) Assignee: LG INNOTEK CO., LTD., Seoul (KR)

(21) Appl. No.: 19/486,509

(22) PCT Filed: May 23, 2024
(86) PCT No.: PCT/KR2024/095849

§ 371 Date: Nov. 21, 2025

(30) Foreign Application Priority Data
May 24, 2023 (KR) 10-2023-0067179

(51) Int. Cl. B32B 15/08; B32B 3/26; B32B 7/12; G06F 1/16

(52) U.S. Cl. CPC B32B 15/08; B32B 3/266; B32B 7/12; G06F 1/1641; G06F 1/1643; G06F 1/1652; B32B 2457/206; B32B 2457/208

(57) ABSTRACT

An elastic member according to an embodiment includes a first layer and a third layer on the first layer, wherein the first layer includes a metal, the third layer includes a base material and a plurality of fibers disposed in the base material, the first layer includes a first region and a second region, a plurality of pattern parts are disposed in the first region, and the third layer has a flatness ratio of 0.05 mm to 0.1 mm.

### TECHNICAL FIELD

An embodiment relates to an elastic member and a display device including the same.

### BACKGROUND ART

Recently, demand for foldable display devices that are easy to carry and may display images on a large screen is increasing.

The foldable display device is folded when portable and unfolded when displaying an image. Accordingly, it is possible to facilitate the user's portability while increasing a display region.

The foldable display device can be folded and unfolded repeatedly. Accordingly, the foldable display device may include an elastic member that can be bent in one direction.

The elastic member can be bent to a curvature within a set size range. The elastic member generates stress when bent. To reduce the stress, a plurality of openings may be formed in a folding region of the elastic member.

The elastic member may include a plurality layers. For example, the elastic member may include a first layer, a second layer, and a third layer. Alternatively, the second layer may be omitted.

The third layer may be disposed at an uppermost portion of the elastic member. The elastic member can prevent wrinkles from forming by using the third layer. Furthermore, the elastic member may have a flatness ratio improved by the third layer.

The opening is formed in the first layer. The third layer is disposed on the first layer. Accordingly, a surface flatness of the third layer may be reduced due to the opening. Furthermore, a thickness of the third layer may be increased to enhance the surface flatness of the third layer. However, in this case, a thickness of the display device including the elastic member may increase.

Therefore, a new elastic member structure capable of resolving the above-described problems is required.

Meanwhile, Korean Patent Publication No. KR10-2018-0079091 (Jul. 10, 2018) discloses a prior art related to an elastic member.

### DISCLOSURE

### Technical Problem

An embodiment provides an elastic member having an improved flatness ratio.

The embodiment provides an elastic member having a thin thickness.

### Technical Solution

An elastic member according to an embodiment includes a first layer and a third layer on the first layer, wherein the first layer includes a metal, the third layer includes a base material and a plurality of fibers disposed in the base material, the first layer includes a first region and a second region, a plurality of pattern parts are disposed in the first region, and the third layer has a flatness ratio of 0.05 mm to 0.1 mm.

### Advantageous Effects

An elastic member according to an embodiment has a thin thickness and an improved flatness ratio.

The elastic member includes a first layer, a second layer, and a third layer.

A plurality of pattern parts are formed in the first layer. The elastic member is easily folded by the pattern parts.

The pattern parts are formed after bonding the first layer, the second layer, and the third layer. Accordingly, a flatness ratio of the third layer can be prevented from being reduced by the pattern parts.

Furthermore, a thickness of the third layer can be reduced. That is, the thickness of the third layer need not be increased to compensate for a reduction in flatness ratio caused by the pattern parts.

Since the thickness of the third layer is reduced, a thickness of the elastic member is also reduced. Accordingly, a slim display device can be manufactured.

Furthermore, since the flatness ratio of the third layer is improved, the flatness ratio of the elastic member is increased. Accordingly, a panel can be easily disposed on the elastic member.

### DESCRIPTION OF DRAWINGS

FIG. 1 is a perspective view of a display device according to an embodiment.

FIG. 2 is a perspective view of an elastic member according to an embodiment.

FIG. 3 is a side view of an elastic member according to an embodiment before folding.

FIG. 4 is a side view of an elastic member according to an embodiment after folding.

FIGS. 5 and 6 are cross-sectional views of a layer structure of an elastic member according to an embodiment.

FIGS. 7 and 8 are top views of a first layer of an elastic member according to an embodiment.

FIG. 9 is a perspective view of a third layer of an elastic member according to an embodiment.

FIG. 10 is a photograph of a cross-sectional view taken along a A-A′ region of FIG. 9.

FIGS. 11 to 13 are drawings illustrating a method for manufacturing an elastic member according to an embodiment.

FIG. 14 is a plan view of an elastic member according to an embodiment.

FIG. 15 is a cross-sectional view taken along a B-B′ region of FIG. 14.

FIG. 16 is an enlarged view of region A of FIG. 15.

FIG. 17 is another plan view of an elastic member according to an embodiment.

FIG. 18 is a cross-sectional view taken along a C-C′ region of FIG. 17.

FIG. 19 is an enlarged view of region B of FIG. 18.

FIGS. 20 and 21 are drawings illustrating the flatness ratio of elastic members according to embodiments and comparative examples.

FIG. 22 is a cross-sectional view of a folding support including an elastic member according to an embodiment.

FIG. 23 is a cross-sectional view of a display device including a folding support according to an embodiment.

FIG. 24 is a drawing illustrating an application example of a display device according to an embodiment.

### MODES OF THE INVENTION

Hereinafter, embodiments of the present disclosure will be described in detail with reference to the accompanying drawings. However, the spirit and scope of the present disclosure is not limited to a part of the embodiments described, and may be implemented in various other forms, and within the spirit and scope of the present disclosure, one or more of the elements of the embodiments may be selectively combined and redisposed. In addition, unless expressly otherwise defined and described, the terms used in the embodiments of the present disclosure (including technical and scientific terms) may be construed the same meaning as commonly understood by one of ordinary skill in the art to which the present disclosure belongs, and the terms such as those defined in commonly used dictionaries may be interpreted as having a meaning that is consistent with their meaning in the context of the relevant art. In addition, the terms used in the embodiments of the present disclosure are for describing the embodiments and are not intended to limit the present disclosure.

In this specification, the singular forms may also include the plural forms unless specifically stated in the phrase, and may include at least one of all combinations that may be combined in A, B, and C when described in “at least one (or more) of A (and), B, and C”.

Further, in describing the elements of the embodiments of the present disclosure, the terms such as first, second, A, B, (a), and (b) may be used. These terms are only used to distinguish the elements from other elements, and the terms are not limited to the essence, order, or order of the elements.

In addition, when an element is described as being “connected”, “coupled”, or “contacted” to another element, it may include not only when the element is directly “connected” to, “coupled” to, or “contacted” to other elements, but also when the element is “connected”, “coupled”, or “contacted” by another element between the element and other elements.

In addition, when described as being formed or disposed “on (over)” or “under (below)” of each element, the “on (over)” or “under (below)” may include not only when two elements are directly connected to each other, but also when one or more other elements are formed or disposed between two elements.

Further, when expressed as “on (over)” or “under (below)”, it may include not only the upper direction but also the lower direction based on one element.

Hereinafter, an elastic member, a folding support and a display device including the elastic member according to an embodiment will be described with reference to drawings.

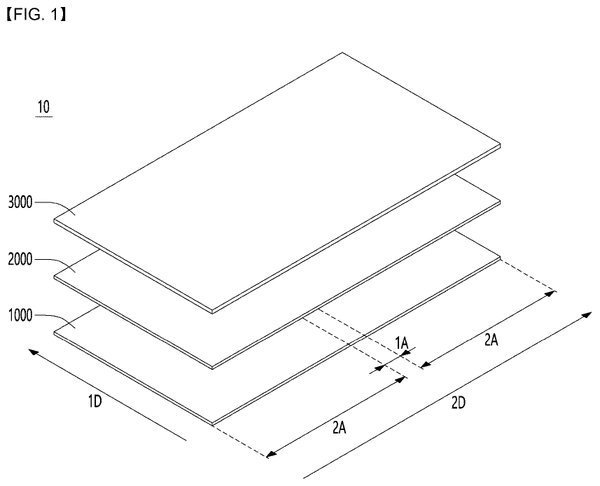

FIG. 1 is a perspective view of a display device. FIGS. 2 to 6 are perspective views and cross-sectional views of the elastic member.

Referring to FIG. 1, a display device 10 includes an elastic member 1000 and a panel. The panel may include at least one of a display panel 2000 and a touch panel 3000. For convenience of explanation, the panel will be described below as including the display panel 2000 and the touch panel 3000.

The elastic member 1000, the display panel 2000, and the touch panel 3000 may be adhered to each other using an adhesive layer or the like.

The elastic member 1000 supports the display panel 2000 and the touch panel 3000. The elastic member 1000 may be a supporting substrate supporting the display panel 2000 and the touch panel 3000.

The elastic member 1000 includes at least one of a metallic material and a non-metallic material. For example, the elastic member 1000 may include a plurality of layers. The plurality of layers may include at least one of the metallic material and the non-metallic material.

For example, the elastic member 1000 may include at least one of a metal, a metal alloy, a plastic, a composite material (e.g., a carbon fiber reinforced plastic, a magnetic or conductive material, a glass fiber reinforced material, etc.), ceramic, sapphire, and glass.

The elastic member 1000 has elasticity. Accordingly, the elastic member 1000 may be bent in one direction. For example, the elastic member 1000 may be folded in one direction. The elastic member 1000 may be a display substrate applied to a foldable display device.

The elastic member 1000 is defined in a first direction 1D and a second direction 2D different direction from the first direction 1D. For example, the first direction 1D is defined as a same direction as a folding axis of the elastic member 1000. In addition, The second direction 2D is defined as a direction perpendicular to the first direction 1D.

Hereinafter, for convenience of explanation, the first direction 1D is defined as the same direction as the folding axis. Furthermore, the first direction 1D is defined as a width direction of the elastic member 1000. Furthermore, the second direction 2D is defined as a length direction of the elastic member 1000.

The elastic member 1000 may include at least two regions. For example, the elastic member 1000 may include a first region 1A and a second region 2A.

The first region 1A is defined as a region where the elastic member 1000 folds. In other words, the first region 1A is a folding region.

In addition, the second region 2A is defined as a region where the elastic member 1000 does not fold. In other words, the second region 2A is an unfolding region.

The display panel 2000 is disposed on the elastic member 1000.

The display panel 2000 may include a plurality of pixels, each including a switching thin film transistor, a driving thin film transistor, a capacitor, and an organic light emitting diode (OLED). The organic light emitting diode can be deposited at a relatively low temperature. Therefore, it has low power consumption and high brightness, making it suitable for use in foldable display devices. Here, a pixel refers to a minimum unit for displaying an image. The display panel displays an image through a plurality of pixels.

The display panel 2000 may include a substrate, a gate line disposed on the substrate, a data line and a common power line intersecting the gate line in an insulated manner. Generally, one pixel may be defined by a boundary between the gate line, the data line, and the common power line.

The substrate may include a flexible material, such as a plastic film. The display panel 2000 may be formed by arranging organic light-emitting diodes and pixel circuits on a flexible film.

The touch panel 3000 is disposed on the display panel 2000. The touch panel 3000 applies a touch function to the foldable display device. Alternatively, the touch panel may be omitted in a foldable display device that only displays images without the touch function.

The touch panel 3000 includes a substrate and touch electrodes disposed on the substrate. The touch electrodes can detect a position of an input device touching the foldable display device using a capacitive or resistive method.

The substrate of the touch panel 3000 may include a flexible material, such as a plastic film. The touch panel 3000 may be implemented by arranging touch electrodes on the flexible film.

The touch panel 3000 may be formed integrally with the display panel 2000. For example, the touch panel 3000 may be formed integrally with the display panel 2000 in an on-cell or in-cell manner. Accordingly, the substrate of the touch panel 3000 may be a substrate of the display panel or a component of the display panel. Accordingly, the touch panel 3000 and the display panel 2000 may be formed integrally. Consequently, a thickness of the foldable display device can be reduced.

The elastic member 1000 and the display panel 2000 may have different sizes.

For example, an area of the elastic member 1000 may be 90% or more and 110% or less of the area of the display panel 2000. Specifically, the area of the elastic member 1000 may be 95% or more and 105% or less of the area of the display panel 2000. More specifically, the area of the elastic member 1000 may be 97% or more and 100% or less of the area of the display panel 2000.

If the area of the elastic member 1000 is less than 90% of the area of the display panel 2000, a supporting force of the elastic member 1000 for supporting the display panel 2000 and the touch panel 3000 is reduced. Accordingly, curling may occur in the unfolding region of the elastic member 1000.

In addition, if the area of the elastic member 1000 exceeds 110% of the area of the display panel 2000, a bezel region of the foldable display device may increase.

Meanwhile, although not shown in the drawing, a foldable display device cover window may be additionally disposed above the touch panel 3000 or above the display panel 2000 (if the touch panel is omitted). The cover window may protect the foldable display device.

Referring to FIG. 2, the elastic member 1000 may be bent in one direction.

In detail, the elastic member 1000 may include a first surface 1S and a second surface 2S opposite the first surface 1S. The elastic member 1000 may be bent such that the first surface 1S or the second surface 2S faces each other. Accordingly, the elastic member 1000 can be bent so that a surface on which the panels are disposed faces each other. Alternatively, the elastic member 1000 can be bent so that an opposite surface of the surface on which the panels are disposed faces each other.

However, the embodiment is not limited thereto. For example, the elastic member 1000 may include a plurality of first regions and a plurality of second regions. Accordingly, the first and second surfaces of the elastic member may be bent so that the first and second surfaces alternately face each other.

Hereinafter, the elastic member will be described as being bent in a direction such that the first surface 1S faces each other.

As explained above, the elastic member 1000 includes a first region 1A and a second region 2A. The first region 1A and the second region 2A are regions defined when the elastic member 1000 is bent.

In detail, when the elastic member 1000 is bent in one direction, the elastic member 1000 can be divided into a first region 1A, which is a folding region, and a second region 2A, which is an unfolding region.

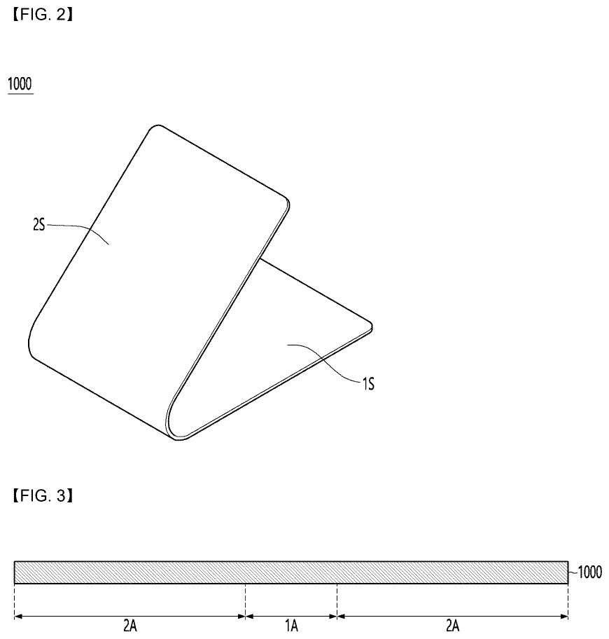

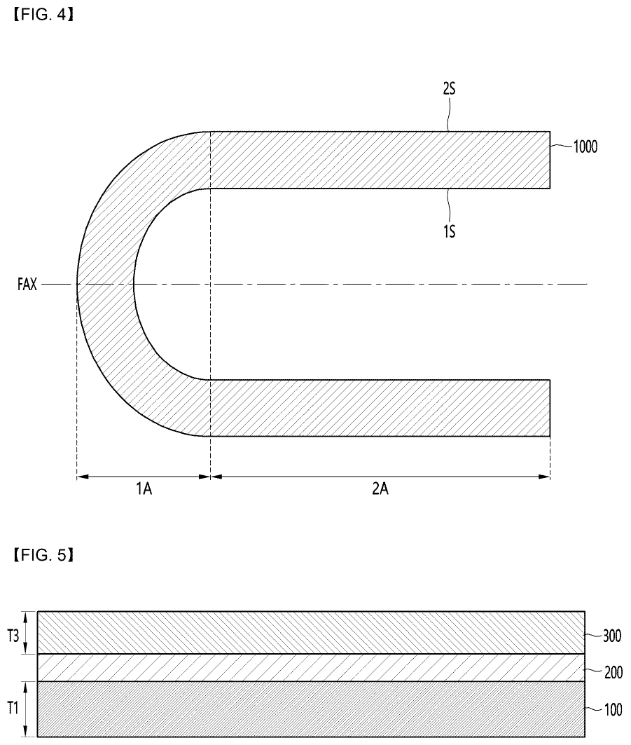

Referring to FIGS. 3 and 4, the elastic member 1000 includes a first region 1A that is bent. In addition, the elastic member 1000 includes a second region 2A that is not bent.

The second region 2A may be formed on left and right sides of the first region 1A, respectively. That is, the second region 2A may be disposed at both ends of the first region 1A. That is, the first region 1A may be disposed between the second region 2A.

However, the embodiment is not limited thereto. For example, the first region 1A may be further formed outside the second region 2A.

Sizes of the first region 1A and the second region 2A may be different. For example, an area of the second region 2A may be larger than that of the first region 1A.

For example, the area of the first region 1A may be 1% to 30% of a total area of the elastic member 1000. Specifically, the area of the first region 1A may be 5% to 20% of the total area of the elastic member 1000. More specifically, the area of the first region 1A may be 10% to 15% of the total area of the elastic member 1000.

If the area of the first region 1A is less than 1% of the total area of the elastic member 1000, cracks may occur at an interface between the folding region and the unfolding region of the elastic member. Accordingly, the folding reliability of the elastic member 1000 may be reduced.

Furthermore, if the area of the first region 1A exceeds 30% of the total area of the elastic member 1000, curling may occur in the first region 1A when folding the elastic member.

In FIGS. 3 and 4, the first region 1A is illustrated as being located at a center of the elastic member 1000. However, the embodiment is not limited thereto. For example, the first region 1A may be located at one end and another end regions of the elastic member 1000.

Referring to FIG. 4, the elastic member 1000 is bent in one direction with respect to the folding axis. Specifically, the elastic member 1000 is folded along the folding axis in a direction in which the first surface 1S faces each other.

The first region 1A may be defined as a region in which a curvature (R) is formed. In addition, the second region 2A may be defined as a region in which no curvature (R) is formed. Alternatively, the second region 2A may be defined as a region in which a curvature is close to 0.

A plurality of pattern parts may be formed in at least one of the first region 1A and the second region 2A. The stress generated when folding the elastic member 1000 by the pattern part can be reduced. The pattern parts will be described below.

The elastic member 1000 may extend from a center of the folding axis, with a decreasing curvature (increasing curvature radius). Alternatively, the elastic member 1000 may extend from the center of the folding axis, with an increasing curvature. Accordingly, a folding shape of the elastic member 1000 may be formed in various ways.

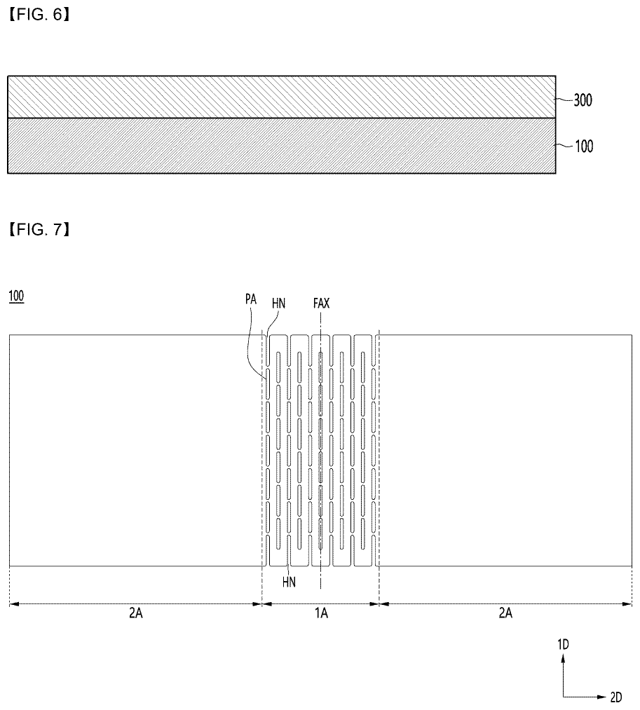

Referring to FIGS. 5 and 6, the elastic member 1000 includes a plurality of layers. The elastic member 1000 may include at least one of a first layer 100, a second layer 200, and a third layer 300.

Referring to FIG. 5, the elastic member 1000 includes the first layer 100, a second layer 200 on the first layer 100, and a third layer 300 on the second layer 200. Alternatively, referring to FIG. 6, the elastic member 1000 includes the first layer 100 and a third layer 300 on the first layer 100.

The first layer 100 may include a metal. For example, the first layer 100 may include a metal or a metal alloy. For example, the first layer 100 may include at least one of stainless steel (SUS) and copper (Cu). Alternatively, the first layer 100 may include a copper alloy including at least one of nickel (Ni), chromium (Cr), iron (Fe), titanium (Ti), manganese (Mn), molybdenum (Mo), silver (Ag), zinc (Zn), nitrogen (N), and aluminum (Al).

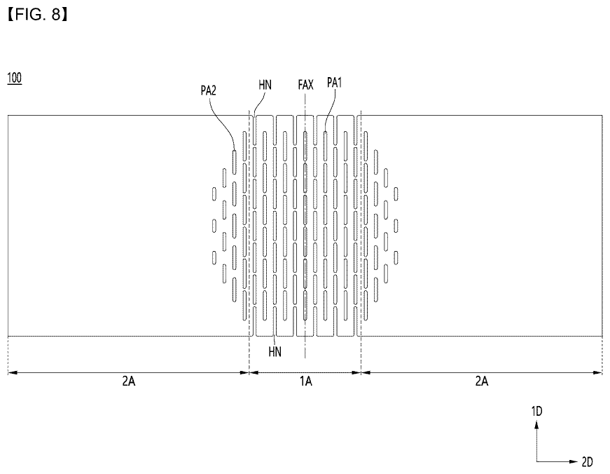

The first layer 100 includes a plurality of pattern parts. Referring to FIG. 6, a plurality of pattern parts are formed in the first region 1A of the first layer 100. Alternatively, referring to FIG. 7, a plurality of pattern parts are formed in the first region 1A and the second region 2A of the first layer 100. That is, a plurality of pattern parts (P) are formed in at least one of a folding region and a unfolding region of the first layer 100.

Referring to FIG. 7, a plurality of pattern parts PA are formed in the first region 1A of the first layer 100. The pattern parts PA may be formed by entirely or partially removing the first layer 100. That is, the pattern parts PA may be holes or grooves formed in the first layer 100.

The stress of the first layer 100 is reduced by the pattern parts PA. Accordingly, the elastic member 1000 is easily folded in the first region 1A.

Alternatively, referring to FIG. 8, a plurality of pattern parts are arranged in the first region 1A and the second region 2A of the first layer 100. Specifically, a first pattern part PA1 is formed in the first region 1A. In addition, a second pattern part PA2 is formed in the second region 2A. The first pattern part PA1 and the second pattern part PA2 may be formed by entirely or partially removing the first layer. That is, the first pattern part PA1 and the second pattern part PA2 may be holes or grooves formed in the first layer 100.

Sizes of the plurality of second pattern parts PA2 may be different. Specifically, a size of the second pattern part PA2 may decrease as it moves away from the folding axis (FAX). Alternatively, a size of the second pattern part PA2 may decrease as it moves away from the first region 1A. That is, the second pattern part PA2 may have a gradient pattern.

The stress of the first layer 100 is reduced by the first pattern part PA1. Accordingly, the elastic member 1000 is easily folded in the first region 1A. In addition, a stress difference between the first region 1A and the second region 2A is reduced by the second pattern part PA2. Accordingly, cracks can be prevented from occurring at a boundary between the first region 1A and the second region 2A.

The first layer 100 may include a hinge part HN. Specifically, a plurality of hinge parts HN may be formed in the first region 1A of the first layer 100. The hinge part HN is formed by opening an end region of the first layer 100. The first layer 100 may begin folding from an outermost hinge part among the plurality of hinge parts HN. The first region 1A and the second region 2A may be distinguished depending on a presence or absence of the hinge part.

The first layer 100 may have a set thickness. A thickness T1 of the first layer 100 may be 30 μm, 50 μm, 100 μm, or 150 μm or more. For example, the thickness of the first layer 100 may be 30 μm to 200 μm.

The second layer 200 may be disposed on the first layer 100. The second layer 200 may be disposed on the first layer 100. Additionally, when the elastic member 1000 includes the second layer 200, the third layer 300 may be disposed on the second layer 200. Accordingly, the second layer 200 is disposed between the first layer 100 and the third layer 300.

The second layer 200 may include an adhesive. The second layer 200 may be an adhesive layer. The first layer 100 and the third layer 300 are adhered by the second layer 200.

For example, the second layer 200 may include a pressure-sensitive adhesive (PSA).

The third layer 300 is disposed on the first layer 100 or the second layer 200. When the elastic member 1000 includes the second layer 200, the third layer 300 is disposed on the second layer 200. Furthermore, when the elastic member 1000 does not include the second layer 200, the third layer 300 is disposed on the first layer 100.

A surface of the elastic member 1000 may be planarized by the third layer 300. The first layer 100 includes a plurality of pattern parts. Accordingly, a planarity of the surface of the first layer 100 is reduced. Therefore, if the panel is directly disposed on the first layer 100, an adhesive strength between the elastic member 1000 and the panel may be reduced.

Therefore, the third layer 300 may be disposed on the first layer 100. By this, the surface of the elastic member 100 can be flattened. Accordingly, the adhesive strength between the elastic member 1000 and the panel can be improved.

The third layer 300 may include a metal or a non-metal. For example, the third layer 300 may include a non-metal. For example, the third layer 300 may include a plastic. The third layer 300 may include a material with high elasticity and strength. For example, the third layer 300 may include a material containing fibers. For example, the third layer 300 may include carbon fiber reinforced plastics (CFRP) or glass fiber reinforced plastic (GFRP).

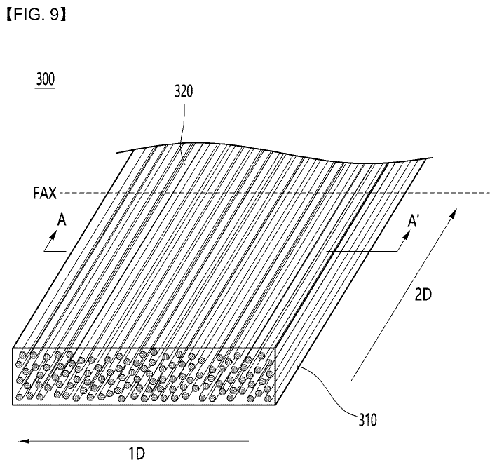

Referring to FIGS. 9 and 10, the third layer 300 includes a base material 310 and a plurality of fibers 320. The fibers 320 are arranged within the base material 310.

The base material 310 may support the fibers 320.

The base material 310 may include a resin material. For example, the base material 310 may include at least one resin material selected from the group consisting of polyimide, polysulfone, polyphenylene sulfide, polyamide-imide, polyether ether ketone, liquid-crystal polyester, polyamide, polyoxymethylene, polycarbonate, polybutylene terephthalate, modified polyphenylene oxide, epoxy, and acrylate.

The fiber 320 is disposed within the base material 310. For example, the fiber 320 may be impregnated into the base material 310.

The fiber 320 may include an elastic material. For example, the fiber 320 may include at least one of carbon fiber, glass fiber, and ceramic fiber.

The fiber 320 may have a set length and a set diameter. For example, the fiber 320 may have a diameter of 0.0001 mm to 0.01 mm. Furthermore, the length of the fiber 320 may vary depending on the size of the third layer 300.

The length of the fiber 320 may extend in a set direction. Specifically, the length of the fiber 320 may extend in a longitudinal direction of the elastic member 1000. That is, the length of the fiber 200 may extend in the second direction (2D). That is, the length of the fiber 320 can extend in a direction perpendicular to the folding axis (FAX). Accordingly, the elastic member 1000 can be easily bent.

The third layer 300 can have a thickness within a set range. The thickness of the third layer 300 can be defined by the thickness of the base material 310. The thickness T3 of the third layer 300 can be 15 μm or more. More specifically, the thickness T3 of the third layer 300 can be 15 μm to 50 μm. More specifically, the thickness T3 of the third layer 300 can be 30 μm to 40 μm.

If the thickness T3 of the third layer 300 is less than 15 μm, it becomes difficult to arrange the fiber within the third layer 300. Accordingly, the process efficiency for manufacturing the third layer 300 may be reduced. Furthermore, if the thickness T3 of the third layer 300 exceeds 50 μm, the thickness of the display device including the elastic member increases. Consequently, the folding reliability of the display device may be reduced. Furthermore, if the thickness T3 of the third layer 300 exceeds 50 μm, the number of fibers 320 in the third layer 300 increases. Consequently, a reaction force of the elastic member increases. Consequently, the force required to restore the elastic member after folding increases, thereby reducing the folding reliability of the elastic member.

As previously described, the surface of the elastic member 1000 can be flattened by the third layer 300. The third layer 300 is disposed in a region where the pattern part is disposed and in a region where the pattern part is not disposed. The third layer 300 may be disposed on the first layer 100 or the second layer 200 in a roll-to-roll manner. At this time, the surface characteristics of the third layer 300 may change in a region where the pattern part is formed. This may reduce a flatness ratio of the third layer 300. To solve this issue, when the thickness of the third layer 300 is increased, there is a problem that the thicknesses of the elastic member 1000 and the display device 10 are increased. Furthermore, when the thickness of the third layer 300 is increased, there is a problem that the reaction force of the elastic member is increased. This reduces the folding reliability of the elastic member.

The embodiment can solve the above-described problems.

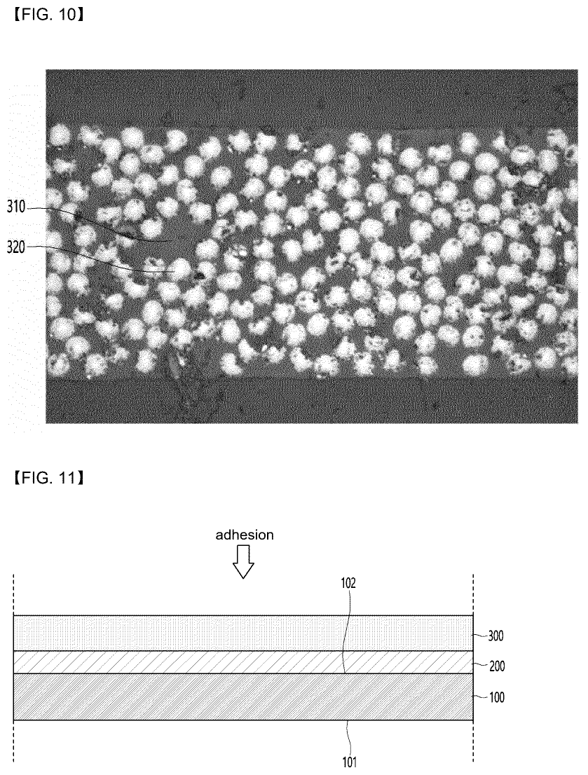

FIGS. 11 to 13 are drawings illustrating a method for manufacturing an elastic member according to the embodiment.

Referring to FIG. 11, the first layer 100, the second layer 200, and the third layer 300 are prepared. Next, the first layer 100, the second layer 200, and the third layer 300 are bonded. Specifically, the second layer 200, which is an adhesive layer, is disposed on the first layer 100. Next, the third layer 300 is bonded on the first layer 100.

Thereby, the first layer 100 is defined as having a first-first surface 101 exposed to the outside and a first-second surface 102 opposite the first-first surface 101. The adhesive layer 200 is disposed on the first-second surface 102.

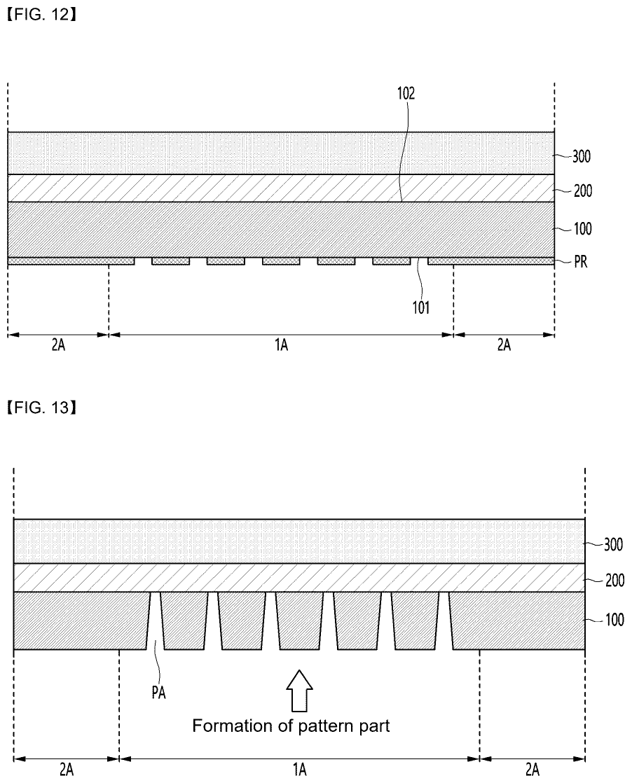

Referring to FIG. 12, a region of the first layer 100 is designated. In detail, the first layer 100 is divided into the first region 1A and the second region 2A. The first region 1A is defined as a folding region, and the second region 2A is defined as an unfolding region.

Next, a photosensitive material (PR) is disposed on the first layer 100. The photosensitive material (PR) is disposed on the first-first surface 101. The photosensitive material (PR) is disposed on the first region 1A and the second region 2A. When the pattern part is formed only on the first region 1A, the photosensitive material may be entirely disposed on the second region 2A, and a photosensitive pattern may be disposed on the first region 1A. Alternatively, when the pattern part is formed in the first region 1A and the second region 2A, a photosensitive pattern may be disposed in the first region 1A and the second region 2A.

Referring to FIG. 13, the pattern part can be formed in the first layer 100. Specifically, a region of the first layer 100 where the photosensitive pattern material is not disposed can be removed.

A process of forming the pattern part can be performed using various methods. For example, the pattern part can be formed using an etchant capable of etching the first layer 100. Specifically, the etchant can etch the first layer 100 in a direction from the first-first surface 101 to the first-second surface 102. Since the etchant only etches the first layer 100, etching of layers other than the first layer 100 can be prevented.

Alternatively, the pattern part can be formed using a laser. Specifically, the laser can be irradiated in a direction toward the first-first surface 101. Accordingly, the first layer 100 can be removed from the first-first surface 101 toward the first-second surface 102. Accordingly, a pattern part having a fine size can be formed.

According to the embodiment, the elastic member forms the pattern part after bonding the third layer. Accordingly, the third layer is disposed on the first layer 100 where the pattern part is not formed. Accordingly, when bonding the third layer, the flatness ratio of the third layer can be prevented from decreasing due to the pattern part. Furthermore, even if the thickness of the third layer is reduced, it may be prevented the flatness ratio of the third layer from decreasing.

Accordingly, the thickness of the elastic member is reduced. Furthermore, the thickness of the display device including the elastic member is reduced. Furthermore, the number of fibers in the third layer is reduced, thereby reducing the reaction force of the elastic member. Consequently, the folding reliability of the elastic member is improved.

Specifically, the elastic member includes a third layer having a thickness of 15 μm to 50 μm. The flatness ratio of the third layer is defined as a difference in height between a highest point and a lowest point of the upper surface of the third layer. The flatness ratio of the third layer may be 0.1 mm or less. Specifically, the flatness ratio of the third layer may be 0.05 mm to 0.1 mm, 0.06 mm to 0.095 mm, or 0.07 mm to 0.09 mm. More specifically, the flatness ratio in a 90 mm×30 mm region of the third layer overlapping the first region of the first layer may be 0.05 mm to 0.1 mm, 0.06 mm to 0.095 mm, or 0.07 mm to 0.09 mm.

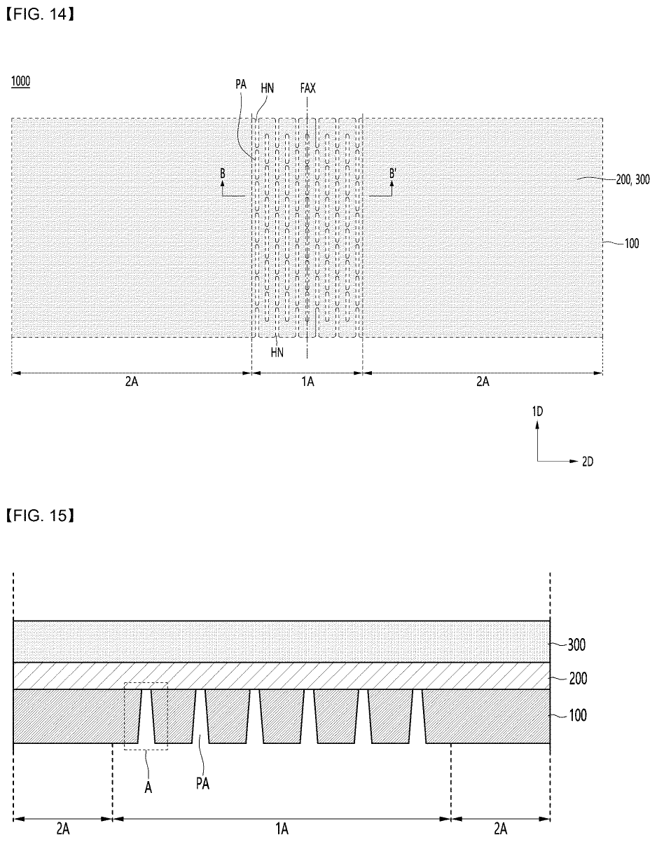

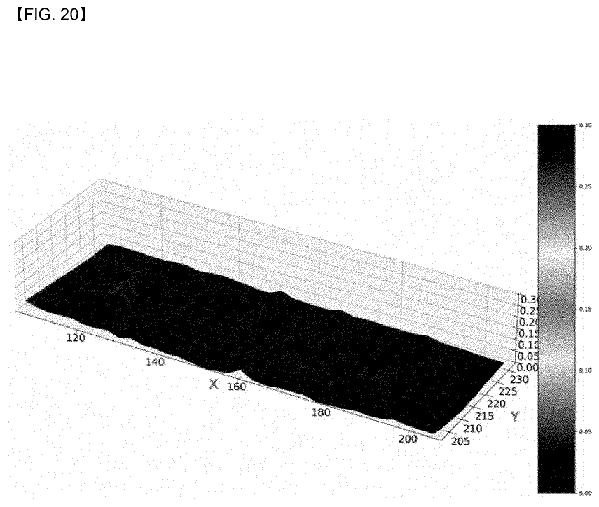

Hereinafter, an elastic member according to an embodiment will be described in detail with reference to FIGS. 14 to 19.

Referring to FIGS. 14 to 16, the elastic member 1000 includes the first layer 100, the second layer 200, and the third layer 300.

The second layer 200 is disposed on the first layer 100, and the third layer 300 is disposed on the second layer 200.

The first layer 100 includes a plurality of pattern parts PA. The pattern parts PA are disposed in at least one of the first region 1A and the second region 2A. For example, the pattern parts PA are disposed in the first region 1A. Alternatively, the pattern parts PA are disposed in the first region 1A and the second region 2A.

A width W of the pattern parts PA may decrease while extending in one direction. In detail, the first layer 100 includes the first-first surface 101 and the first-second surface 102 opposite to the first-first surface 101. The first-second surface 102 is in contact with the adhesive layer 200. The width W of the pattern part PA may decrease while extending from the first-first surface 101 toward the first-second surface 102.

The pattern part PA is formed after adhering the first layer 100, the second layer 200, and the third layer 300. Accordingly, the pattern part PA is formed in one direction from the first-first surface 101 toward the first-second surface 102. Therefore, the width W of the pattern part PA may decrease while extending from the first-first surface 101 toward the first-second surface 102.

Accordingly, a contractile force generated on the first-first surface can be easily utilized when folding the elastic member. Therefore, the folding reliability of the elastic member can be improved.

Referring to FIG. 16, the second layer 200 can be disposed at various locations.

Referring to FIG. 16(a), the second layer 200 is not disposed inside the pattern part PA. The pattern part PA is formed after adhering the first layer 100, the second layer 200, and the third layer 300. Accordingly, a portion of the second layer 200 may be removed during a process of forming the pattern part PA. Consequently, the adhesive characteristics of the second layer 200 may be reduced. Consequently, a residual region of the first layer 100 can be formed in a region between the pattern part PA and the second layer 200. That is, the pattern The part PA may partially penetrate the first layer 100 rather than completely.

Therefore, the formation of the pattern part PA can prevent the second layer 200 from being partially removed. Therefore, the adhesive strength of the second layer 200 can be improved. Accordingly, the reliability of the elastic member can be improved.

Referring to (b) of FIG. 16, the second layer 200 is disposed inside the pattern part PA. In detail, the second layer 200 is divided into a second-first layer 210 and a second-second layer 220. The second-first layer 210 is disposed on the first layer 100. That is, the second-first layer 210 is disposed outside the pattern part PA. The second-second layer 220 is disposed inside the pattern part PA.

The pattern part PA is formed after bonding the first layer 100, the second layer 200, and the third layer 300. Accordingly, when the pattern part PA is formed by penetrating the first layer 100, a portion of the second layer 200 overlapping the pattern part PA may penetrate into an interior of the pattern part PA. Accordingly, the second layer 200 is divided into the second-first layer 210 and the second-second layer 220. A thickness of the second-first layer 210 and a thickness of the second-second layer 220 may be different. For example, the thickness of the second-second layer 220 may be smaller than the thickness of the second-first layer 210.

Since the second layer 200 includes the second-second layer 220, a bonding area of the second layer 200 increases. Accordingly, the adhesive strength of the second layer 200 increases. Accordingly, the adhesive characteristics of the first layer 100 and the third layer 300 increase. As a result, the reliability of the elastic member can be improved.

Referring to (c) of FIG. 16, the second layer 200 is not disposed inside the pattern part PA. Specifically, the second layer 200 may include a void region CA1. The void region CA1 may be positioned in a region corresponding to the pattern part PA.

The pattern part PA is formed after bonding the first layer 100, the second layer 200, and the third layer 300. When the pattern part PA is formed by a laser, a portion of the second layer 200 corresponding to the pattern part PA may be removed together. As a result, the second layer 200 may include the void region CA1.

Since the second layer 200 includes the void region CA1, the sizes of the pattern parts formed in the first layer 100 may be uniform. That is, since all of the pattern parts are formed by penetrating the first layer, a size deviation of the pattern parts can be reduced. Consequently, the stress difference in the first region where the pattern parts are formed can be reduced. Accordingly, the folding characteristics of the elastic member can be improved.

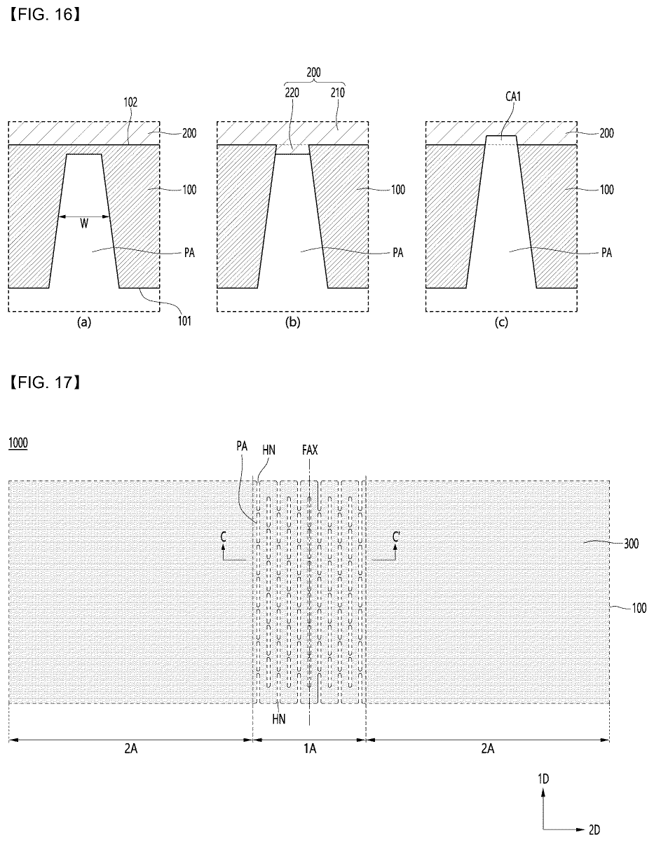

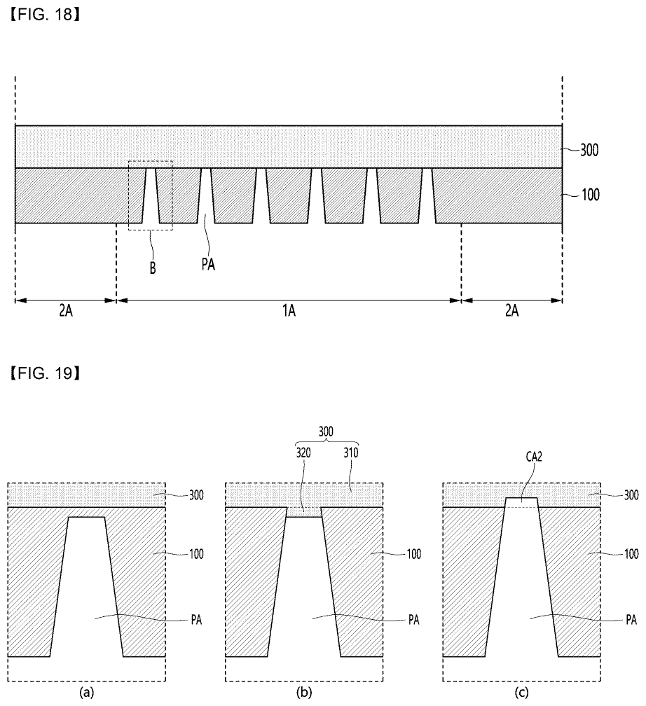

Referring to FIGS. 17 to 19, the elastic member 1000 includes the first layer 100 and the third layer 300.

The third layer 300 is disposed on the first layer 200.

The first layer 100 includes a plurality of pattern parts PA. The pattern parts PA are disposed in at least one of the first region 1A and the second region 2A. For example, the pattern parts PA are disposed in the first region 1A. Alternatively, the pattern parts PA are disposed in the first region 1A and the second region 2A.

Referring to FIG. 19, the third layer 300 may be positioned in various locations.

Referring to FIG. 19(a), the third layer 300 is not disposed inside the pattern part PA. The pattern part PA is formed after bonding the first layer 100 and the third layer 300. Accordingly, a portion of the third layer 300 may be removed during the process of forming the pattern part PA. Consequently, the fibers within the third layer 300 may be cut. If the fibers are cut, a crease may occur in the first region when the elastic member is rolled and unfolded.

Accordingly, a residual region of the first layer 100 may be formed in the region between the pattern part PA and the third layer 300. That is, the pattern part PA may partially penetrate the first layer 100 rather than completely.

Therefore, the formation of the pattern part PA can prevent the third layer 300 from being partially removed. Consequently, the fibers of the third layer 300 can be prevented from being cut. This improves the reliability of the elastic member.

Referring to FIG. 19(b), the third layer 300 is disposed inside the pattern part PA. Specifically, the third layer 300 is divided into a third-first layer 310 and a third-second layer 320. The third-first layer 310 is disposed on the first layer 100. That is, the third-first layer 210 is disposed outside the pattern part PA. The third-second layer 320 is disposed inside the pattern part PA.

The pattern part PA is formed after bonding the first layer 100 and the third layer 300. Accordingly, when the pattern part PA is formed by penetrating the first layer 100, a portion of the third layer 300 overlapping the pattern part PA may penetrate into the interior of the pattern part PA. Accordingly, the third layer 300 is divided into the third-first layer 210 and the third-second layer 320. The thickness of the third-first layer 310 and the thickness of the third-second layer 320 may differ. For example, the thickness of the third-second layer 320 may be less than the thickness of the third-first layer 310.

Since the third layer 300 includes the third-second layer 320, the bonding area of the third layer 300 increases. Consequently, the bonding characteristics between the first layer 100 and the third layer 300 increase. This enhances the reliability of the elastic member.

Referring to (c) of FIG. 19, the third layer 300 is not disposed inside the pattern part PA. Specifically, the third layer 300 may include a void region CA2. The void region CA2 may be positioned in a region corresponding to the pattern part PA.

The pattern part PA is formed after bonding the first layer 100 and the third layer 300. When the pattern part PA is formed by laser, a portion of the third layer 300 corresponding to the pattern part PA may be removed together. Accordingly, the third layer 300 can include the void region CA2.

Since the third layer 300 includes the void region CA2, the size of the pattern parts formed in the first layer 100 can be made uniform. That is, since the pattern parts are all formed by penetrating the first layer, the size deviation of the pattern parts can be reduced. Consequently, the stress difference in the first region where the pattern parts are formed can be reduced. Accordingly, the folding characteristics of the elastic member can be improved.

Hereinafter, the elastic member according to the embodiment will be described in more detail through examples and comparative examples.

### EXAMPLE

A first layer comprising stainless steel (SUS), a second layer comprising a pressure-sensitive adhesive (PSA), and a third layer comprising carbon fiber reinforced plastics (CFRP) are prepared. The third layer has a thickness of 35 μm.

Next, the second layer is disposed between the first layer and the third layer, and the first layer and the third layer are bonded together.

A first region, which is a folding region, and a second region, which is an unfolding region, are defined in the first layer.

Next, a photoresist pattern is formed in the first layer.

Next, an etchant capable of etching the first layer is used to form a hole- or groove-shaped pattern part in the first region, thereby manufacturing an elastic member.

Next, the flatness ratio of the third layer is measured.

Specifically, a random region measuring 90 mm*30 mm is selected from the first region, and the flatness ratio of the third layer is measured. The flatness ratio is measured by calculating the difference between highest and lowest points in the random region.

### COMPARATIVE EXAMPLE

After forming the pattern part on the first layer, the second layer is disposed between the first and third layers, and the first and third layers are bonded to manufacture an elastic member.

Next, the flatness ratio of the third layer is measured.

Specifically, a random region measuring 90 mm*30 mm is selected from the first region, and the flatness ratio of the third layer is measured. The flatness ratio is measured by calculating the difference between the highest and lowest points in the random region.

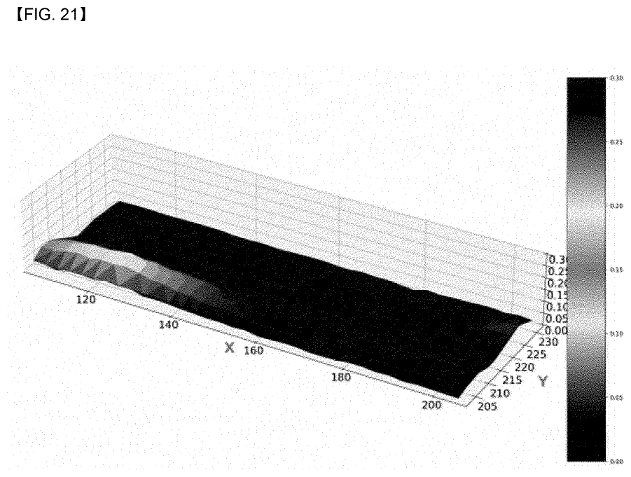

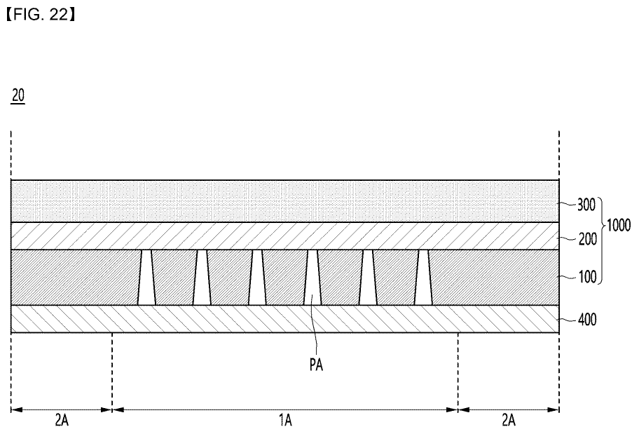

FIG. 20 is a drawing measuring the flatness ratio of a third layer according to an embodiment, and FIG. 21 is a drawing measuring the flatness ratio of a third layer according to a comparative example. In FIGS. 20 and 21, a X-axis represents a flatness ratio measurement length of the third layer, and a Y-axis represents a surface height.

In detail, the flatness ratio of the third layer according to the embodiment is measured as 0.089 mm, and the flatness ratio of the third layer according to the comparative example is measured as 0.138 mm.

In the elastic member according to the comparative example, the third layer is disposed on the first layer on which the pattern part is formed. Accordingly, when the third layer having a thickness of 50 μm or less is disposed on the first layer, the flatness ratio of the third layer is reduced by the pattern part.

In contrast, in the elastic member according to the embodiment, the first layer, the second layer, and the third layer are bonded, and then the pattern part is formed in the first layer. Accordingly, when bonding the third layer, it is not affected by the pattern part. Accordingly, even when a third layer having a thickness of 50 μm or less is disposed on the first layer, the flatness ratio of the third layer is improved. That is, the third layer has a thin thickness and a flatness ratio of 0.1 mm or less.

Hereinafter, with reference to FIG. 22, a folding support 20 including an elastic member according to an embodiment will be described.

Referring to FIG. 22, the folding support 20 includes an elastic member 1000 and a protective layer 400.

The protective layer 400 is disposed below the elastic member 400.

For example, an adhesive layer is disposed between the protective layer 400 and the elastic member 1000. The adhesive layer allows the elastic member 1000 and the protective layer 400 to be bonded together.

The protective layer 400 may have a color. For example, the protective layer 400 may have a black color.

The protective layer 400 may include metal particles. For example, the protective layer 400 may include copper particles. Accordingly, the thermal conductivity of the protective layer 400 may be improved. Accordingly, heat generated in the display device may be dissipated by the protective layer 400.

The protective layer 400 may be disposed in a region corresponding to the first region 1A of the elastic member 1000. Alternatively, the protective layer 400 may be disposed in a region corresponding to the first region 1A and the second region 2A of the elastic member 1000.

For example, the protective layer 400 is disposed in a region corresponding to the first region 1A and the second region 2A of the elastic member 1000. The protective layer 400 may be disposed with an area smaller than a combined area of the first region 1A and the second region 2A. For example, the protective layer 400 may be disposed with an area that is 80% to 90% of the combined area of the first region 1A and the second region 2A of the elastic member.

Furthermore, the thickness of the protective layer 400 may be smaller than an entire thickness of the elastic member 1000. That is, the thickness of the protective layer 400 may be smaller than the sum of the thicknesses of the first layer, the second layer, and the third layer of the elastic member 400.

Hereinafter, a display device including a folding support according to an embodiment will be described with reference to FIG. 23.

Referring to FIG. 23, the display device 10 may include the folding support 20 and the panel layer 500.

The panel layer 500 may include at least one of the display panel and the touch panel.

An adhesive layer may be disposed between the folding support 20 and the panel layer 500. The folding support 20 and the panel layer 500 may be adhered to each other by the adhesive layer.

The elastic member 1000 may flatten an adhesive surface of the elastic member by the third layer 300. Therefore, the elastic member and the panel layer may be easily adhered to each other.

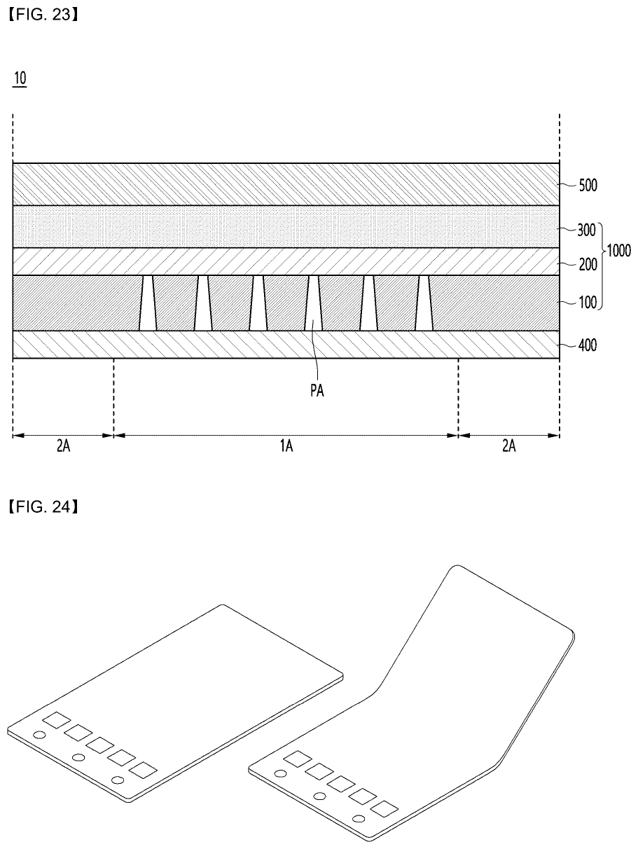

FIG. 24 is a drawing illustrating an example of applying an elastic member according to embodiments.

Referring to FIG. 24, the elastic member according to embodiments can be applied to a flexible or foldable display device that displays a display.

For example, the elastic member according to embodiments can be applied to a flexible display device including a mobile phone or tablet. Thus, the display device can be curved or folded.

The display device can be easily folded by the elastic member. Furthermore, the folding reliability of the display device can be improved.

The characteristics, structures and effects described in the embodiments above are included in at least one embodiment but are not limited to one embodiment. Furthermore, the characteristics, structures, and effects and the like illustrated in each of the embodiments may be combined or modified even with respect to other embodiments by those of ordinary skill in the art to which the embodiments pertain. Thus, it should be construed that contents related to such a combination and such a modification are included in the scope of the embodiment.

The above description has been focused on the embodiment, but it is merely illustrative and does not limit the embodiment. A person skilled in the art to which the embodiment pertains may appreciate that various modifications and applications not illustrated above are possible without departing from the essential features of the embodiment. For example, each component particularly represented in the embodiment may be modified and implemented. In addition, it should be construed that differences related to such changes and applications are included in the scope of the embodiment defined in the appended claims.

1-10. (canceled)

11. An elastic member comprising:
a first layer; and
a third layer on the first layer,
wherein the first layer includes a metal,
wherein the third layer includes a base material and a plurality of fibers disposed in the base material,
wherein the first layer includes a first region and a second region,
wherein a plurality of pattern parts are disposed in the first region, and
wherein the third layer has a flatness ratio of 0.05 mm to 0.1 mm.

12. The elastic member of claim 11, wherein, in a region overlapping the first region, a flatness ratio in a 90 mm×30 mm region of the third layer is 0.05 mm to 0.1 mm.

13. The elastic member of claim 11, wherein the third layer has a thickness of 15 μm to 50 μm.

14. The elastic member of claim 11, wherein the third layer is not disposed inside the pattern part.

15. The elastic member of claim 11, wherein the third layer includes a third-first layer disposed outside the pattern part and a third-second layer disposed inside the pattern part, and
wherein a thickness of the third-second layer is smaller than that of the third-first layer.

16. The elastic member of claim 11, wherein the third layer includes a void region formed in a region corresponding to the pattern part.

17. The elastic member of claim 11, further comprising a second layer disposed between the first layer and the third layer,
wherein the second layer includes an adhesive layer.

18. The elastic member of claim 17, wherein the second layer is not disposed inside the pattern part.

19. The elastic member of claim 17, wherein the second layer comprises a second-first layer disposed outside the pattern part and a second-second layer disposed inside the pattern part, and
wherein a thickness of the second-second layer is smaller than a thickness of the second-first layer.

20. The elastic member of claim 17, wherein the second layer incudes a void region formed in a region corresponding to the pattern part.

21. The elastic member of claim 11, wherein the first layer includes a first-first surface and a first-second surface opposite the first-first surface,
wherein the first-second surface is in contact with the second layer or the third layer, and
wherein a width of the pattern part narrows as it extends from the first-first surface toward the first-second surface.

22. The elastic member of claim 11, wherein the plurality of pattern parts includes a plurality of first pattern parts formed in the first region, and a plurality of second pattern parts formed in the second region,
wherein the first region is a region closer to the folding axis than the second region, and
wherein sizes of the first pattern part and the second pattern part are different.

23. The elastic member of claim 22, wherein each of the first pattern part and the second pattern part has a length in a first direction along which the folding axis extends and a width in a second direction perpendicular to the first direction, and
wherein the length of the first pattern part in the first direction is greater than the length of the second pattern part in the first direction.

24. The elastic member of claim 23, wherein the width of the first pattern part in the second direction is equal to the width of the second pattern part in the second direction.

25. The elastic member of claim 23, wherein the second pattern part includes:
a second-first pattern part closest to the first pattern part;
a second-second pattern part disposed further from the first pattern part than the second-first pattern part; and
a second-third pattern part disposed further from the first pattern part than the second-second pattern part, and
wherein lengths in the first direction of the second-first pattern part, the second-second pattern part, and the second-third pattern part are different.

26. The elastic member of claim 25, wherein the length of the second-first pattern part in the first direction is greater than the lengths of each of the second-second pattern part and the second-third pattern part in the first direction, and
wherein the length of the second-third pattern part in the first direction is less than the lengths of each of the second-first pattern part and the second-second pattern part in the first direction.

27. The elastic member of claim 25, wherein the first layer includes first and second side ends facing each other in the first direction,
wherein each of the second-first pattern part, the second-second pattern part, and the second-third pattern part includes an outer pattern closest to the first side end, and
wherein distances in the first direction from the first side end to the outer patterns of each of the second-first pattern part, the second-second pattern part, and the 2-3 pattern part are different from each other.

28. The elastic member of claim 27, wherein the distance from the first side end to the outer pattern of the second-first pattern part in the first direction is smaller than the distance from the first side end to the outer pattern of each of the second-second pattern part and the second-third pattern part in the first direction, and
wherein the distance from the first side end to the outer pattern of each of the second-third pattern part in the first direction is larger than the distance from the first side end to the outer pattern of each of the second-first pattern part and the second-second pattern part in the first direction.

29. A folding support comprising:
an elastic member according to claim 11; and
a protective layer disposed under the elastic member.

30. A display device comprising:
an elastic member according to claim 11;
a protective layer disposed under the elastic member; and
a panel layer disposed on the elastic member,
wherein the panel layer includes at least one of a display panel and a touch panel.
